(19) United States
(12) Patent Application Publication
(10) Pub. No.: US 2015/0296636 A1
(43) Pub. Date: Oct. 15, 2015

(54) ELECTRONIC APPARATUS FOR SOLAR POWER SYSTEM

(71) Applicant: Chicony Power Technology Co., Ltd., New Taipei City (TW)

(72) Inventors: Ying-Shiang WANG, New Taipei City (TW); Hung-Jui CHANG, New Taipei City (TW); Yu-Jen LAI, New Taipei City (TW)

(73) Assignee: Chicony Power Technology Co., Ltd., New Taipei City (TW)

(21) Appl. No.: 14/250,410

(22) Filed: Apr. 11, 2014

(51) Int. Cl. H05K 5/00; H05K 5/02

(52) U.S. Cl. CPC H05K 5/0056; H05K 5/0004; H05K 5/0247; H05K 5/0221; H05K 5/0239

(57) ABSTRACT

An electronic apparatus for a solar power system includes a first shell, a waterproof member, and a second shell. The first shell has a surrounding plate, a receiving space formed in the surrounding plate, and at least one clasp portion disposed on an inner side of the surrounding plate. A surrounding notch is formed on the top of the surrounding plate.

The waterproof member is filled in the surrounding notch. The second shell has a surrounding protrusion and at least one clasp part disposed on an inner side of the surrounding protrusion. The clasp part snap fits the clasp portion correspondingly to make the surrounding protrusion embedded in the surrounding notch such that the waterproof member is clamped between the surrounding protrusion and the surrounding plate. Thus, waterproof and dustproof of the electronic apparatus are improved.

### BACKGROUND OF THE INVENTION

1. Field of the Invention

The present invention relates to an electronic apparatus for a solar power system and, in particular, to an electronic apparatus for a solar power system such as a solar junction apparatus and a power inverting apparatus.

2. Description of Related Art

As people continue to promote energy saving and environmental protection, solar power technology has become one of the most important industries to develop associated with the energy saving and environmental protection. The government is currently developing the solar power plant and the home solar power station, which makes the solar power technology increasingly widely applicable in modern environment.

The solar power technology mainly converts light energy into electrical energy through the solar panel. Then, the electrical energy generated by the solar panel is delivered for use through cables. Therefore, the solar power technology needs the electronic apparatus for the solar power system such as a solar junction apparatus and a power inverting apparatus. In this way, the cables can undertake the conversion using the solar junction apparatus at the place where the photoelectric conversion occurs or the electrical energy generated by the solar panel is converted from DC into AC by the power inverting apparatus.

However, since the solar junction apparatus or the power inverting apparatus is installed outdoors with the solar panel, the moisture and particles from the environment could enter the inside of the electronic apparatus such as the solar junction apparatus and the power inverting apparatus, causing corrosion of the cables or electronic elements and then adversely affecting the performance of the photoelectric conversion. Accordingly, how to enhance the waterproof and dustproof of the electronic apparatus for the solar power system is one of main improvements in the electronic apparatus for the solar power system.

### SUMMARY OF THE INVENTION

The present invention is to provide an electronic apparatus for a solar power system, which uses corresponding snap fits between clasp parts and clasp portions to make a surrounding protrusion embedded in a surrounding notch such that the surrounding protrusion is pressed against and then deforms a waterproof member which further contacts against a surrounding plate more tightly, improving the waterproof and dustproof of the electronic apparatus for the solar power system.

The present invention provides an electronic apparatus for a solar power system, the electronic apparatus comprising:

a first shell having a surrounding plate, a receiving space formed in the surrounding plate, and at least one clasp portion disposed on an inner side of the surrounding plate, wherein a surrounding notch is formed on the top of the surrounding plate;

a waterproof member filled in the surrounding notch; and

a second shell connected to the first shell and fitted to cover the receiving space correspondingly, wherein the second shell has a surrounding protrusion and at least one clasp part disposed on an inner side of the surrounding protrusion, wherein the at least one clasp part snap fits the at least one clasp portion correspondingly to make the surrounding protrusion embedded in the surrounding notch such that the waterproof member is clamped between the surrounding protrusion and the surrounding plate.

### BRIEF DESCRIPTION OF DRAWING

FIG. 1 is a perspective exploded view of the electronic apparatus for a solar power system according to the first embodiment of the present invention;

FIG. 2 is another perspective exploded view of the electronic apparatus for a solar power system according to the first embodiment of the present invention;

FIG. 3 is a perspective assembled view of the electronic apparatus for a solar power system according to the first embodiment of the present invention;

FIG. 4 is another perspective assembled view of the electronic apparatus for a solar power system according to the first embodiment of the present invention;

FIG. 5 is a cross-sectional schematic view along line 5-5 in FIG. 4;

FIG. 6 is a magnified view of portion A in FIG. 5;

FIG. 7 is a cross-sectional schematic view along line 7-7 in FIG. 4; and

FIG. 8 is a magnified view of portion B in FIG. 7.

### DETAILED DESCRIPTION OF THE INVENTION

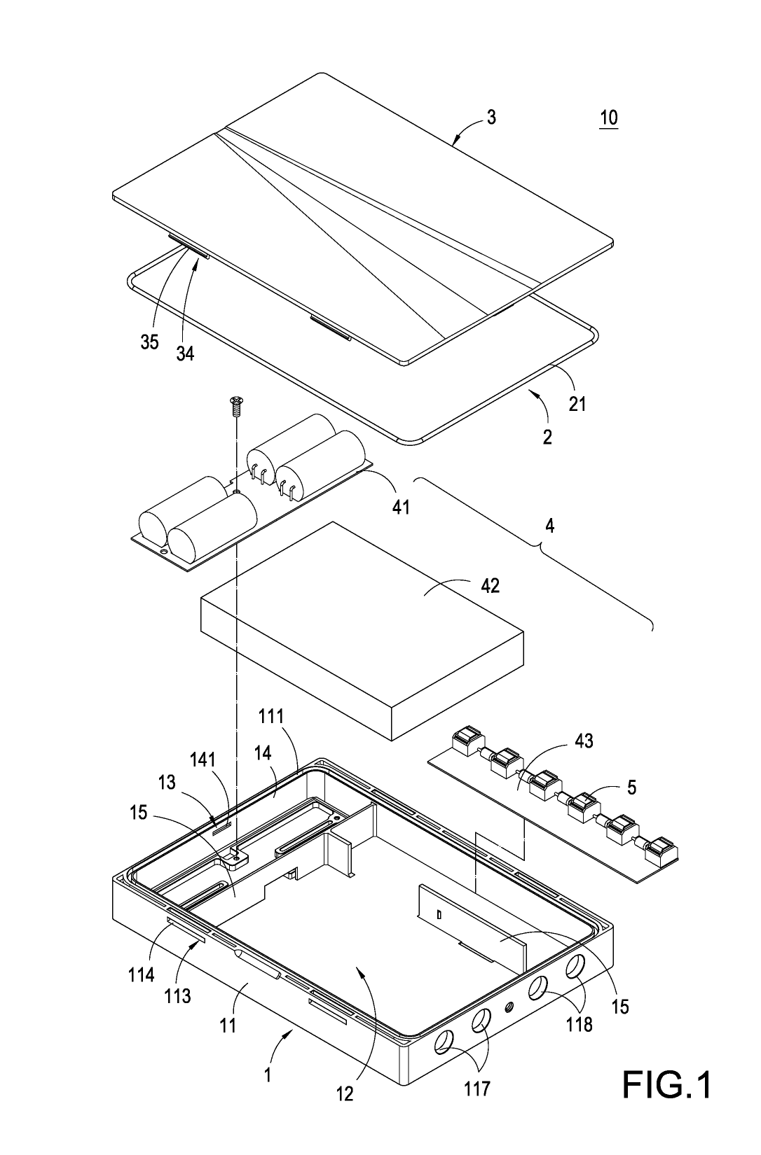

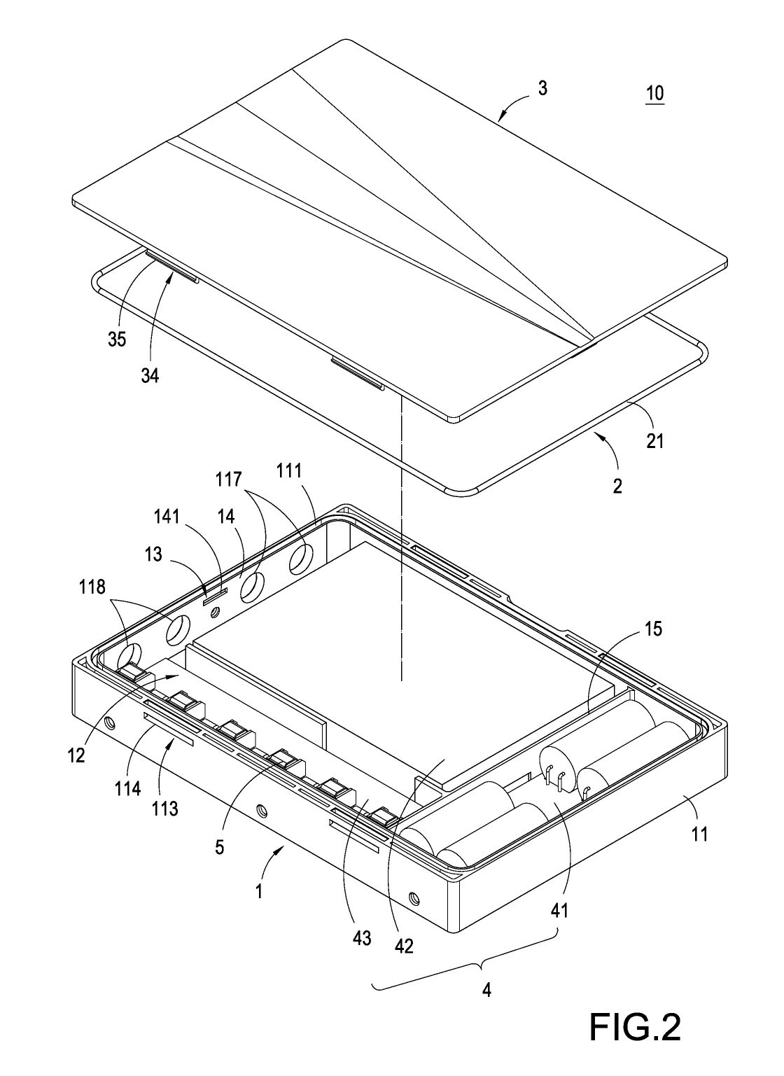

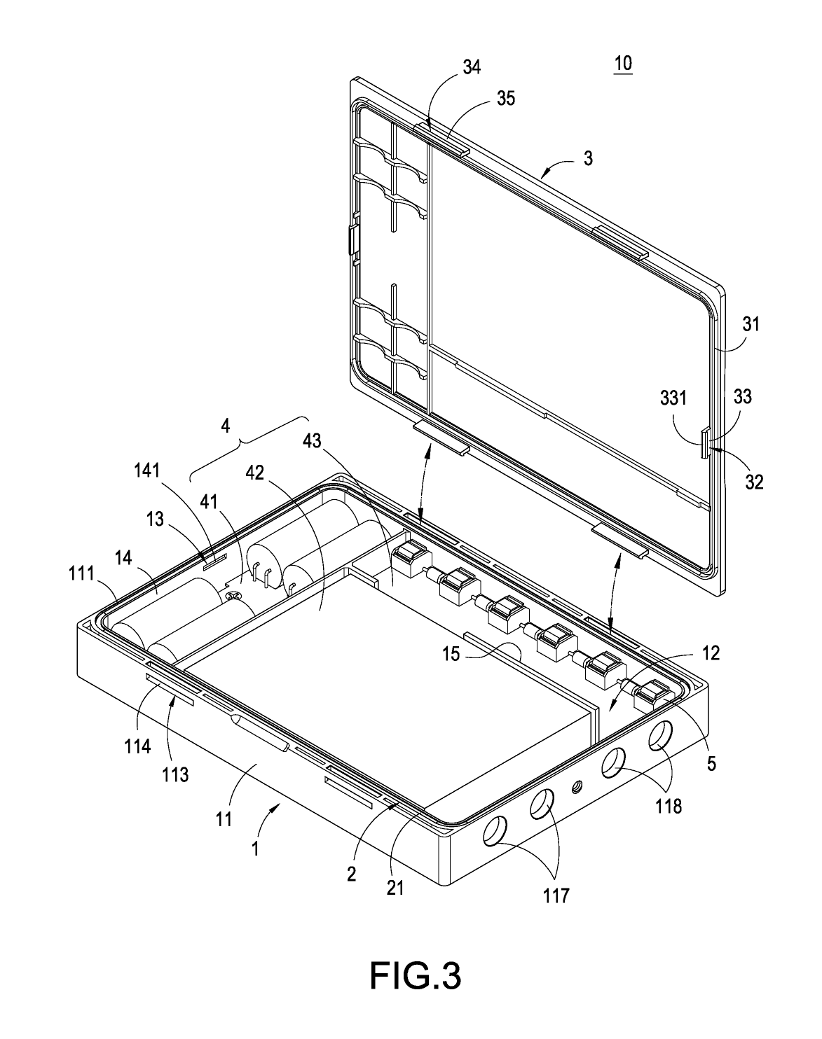

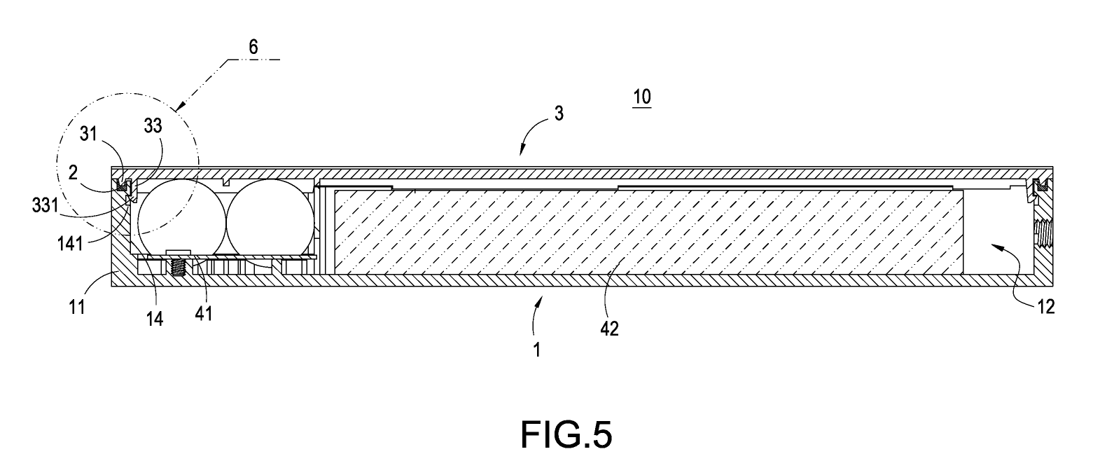

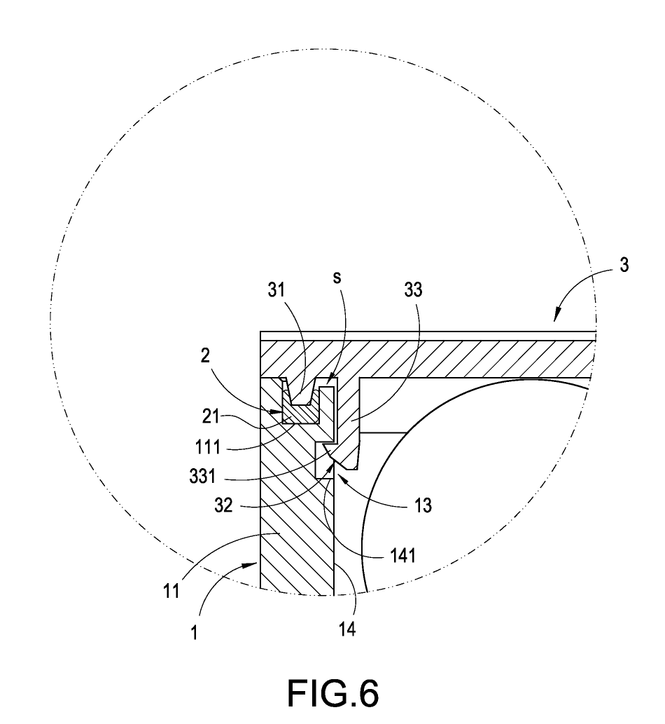

The detailed description and technical details of the present invention will be explained below with reference to accompanying figures. However, the accompanying figures are only for explanation, but not to limit the scope of the present invention. Please refer to FIGS. 1-8. The present invention provides an electronic apparatus for a solar power system according to the first embodiment. The electronic apparatus 10 for a solar power system comprises a first shell 1, a waterproof member 2, and a second shell 3. As shown in FIGS. 1-4, the electronic apparatus 10 may be a power inverting apparatus, a solar junction apparatus, or a combined apparatus integrating a solar junction and a power inverting mechanism. In the current embodiment, the electronic apparatus 10 is the combined apparatus integrating the solar junction and the power inverting mechanism, but not limited to this.

As shown in FIGS. 1-8, the first shell 1 has a surrounding plate 11, a receiving space 12 formed in the surrounding plate 11, and at least one clasp portion 13 disposed on an inner side of the surrounding plate 11. A surrounding notch 111 is formed on the top of the surrounding plate 11. The detailed description is given below.

The surrounding plate 11 has an inner wall 14 on which the clasp portion 13 is formed. The clasp portion 13 is a lock slot 141 formed on the inner wall 14.

Besides, at least one clasp slot 113 is disposed on each of two opposite sides of the surrounding plate 11. The at least one clasp slot 113 is an L-shaped slot 114 formed from the top of the surrounding plate 11 and from the inside to the outside thereof. In the current embodiment, the number of the at least one clasp slot 113 is greater than one, but not limited to this.

Further, a plurality of AC output holes 117 and a plurality of DC output holes 118 are disposed on a side of the surrounding plate 11. The AC output holes 117 are for positioning the AC power transmission cables. The DC output holes 118 are for positioning the DC power transmission cables. Also, a plurality of partitions 15 extend from the first shell 1 toward the receiving space 12.

As shown in FIGS. 1-8, the waterproof member 2 is filled in the surrounding notch 111. The waterproof member 2 is a waterproof ring 21 commonly available in the market. The waterproof member 2 is composed of elastic water stop materials such as rubber and silicon or is made of a PU (Polyurethane) foam disposed in the surrounding notch 111.

As shown in FIGS. 1-8, the second shell 3 is connected to the first shell 1 and fitted to cover the receiving space 12 correspondingly. The second shell 3 has a surrounding protrusion 31 and at least one clasp part 32 disposed on an inner side of the surrounding protrusion 31. The clasp part 32 snap fits the clasp portion 13 correspondingly to make the surrounding protrusion 31 embedded in the surrounding notch 111 such that the waterproof member 2 is clamped between the surrounding protrusion 31 and the surrounding plate 11. Further explanation is given below.

At least one pressing block 33 extends from the second shell 3 toward the receiving space 12. The clasp part 32 is formed at the end of the pressing block 33.

In addition, the clasp part 32 is a latch block 331 protruding from the end of the pressing block 33. The latch block 331 snap fits the lock slot 141 correspondingly such that the clasp part 32 snap fits the clasp portion 13 correspondingly. Likewise, the clasp portion 13 may be a latch block protruding from the inner wall 14 and the clasp part 32 may be a lock slot formed at the end of the pressing block 33, which can have the same function and effect as in the previous configuration.

Further, there is a spacing s between the top of the inner wall 14 and the second shell 3 such that the spacing s is disposed between the clasp part 32 and the clasp portion 13 when the clasp part 32 snap fits the clasp portion 13 accordingly.

In the current embodiment, the numbers of the clasp part 32 and the clasp portion 13 are both greater than one, but not to limited to this. Thus, the pressing block 33 is also plural in number. The pressing blocks 33 are disposed at the opposite ends of the second shell 3 such that when the clasp part 32 at the opposite ends of the second shell 3 snap fit the clasp portions 13 on the opposite sides of the inner wall 14, the surrounding protrusion 31 can be evenly pressed and embedded in the surrounding notch 111, further making the waterproof member 2 evenly clamped between the surrounding protrusion 31 and the surrounding plate 11.

Also, at least one clasp block 34 extends from each of two opposite ends of the second shell 3. The clasp block 34 is an L-shaped protrusion 35 protruding from the second shell 3. The L-shaped protrusion 35 snap fits the L-shaped slot 114 correspondingly such that the clasp block 34 snap fits the clasp slot 113 correspondingly, causing the second shell 3 and the first shell 1 to engage and combine with each other. In the current embodiment, the clasp block 34 is plural in number, but not limited to this.

As shown in FIGS. 1-3, the electronic apparatus 10 for a solar power system of the present invention further comprises a PCB 4 and a plurality of connectors 5. The PCB 4 and the connectors 5 are electrically connected to one another in the receiving space 12. The further description is given below.

The PCB 4 comprises a first PCB 41, a second PCB 42, and a third PCB 43 which are electrically connected to one another. Both the first PCB 41 and the second PCB 42 form a power inverting circuit. The third PCB 43 forms a grounding circuit. The connectors 5 are welded on the third PCB 43. The partitions 15 are disposed among the first PCB 41, the second PCB 42, and the third PCB 43.

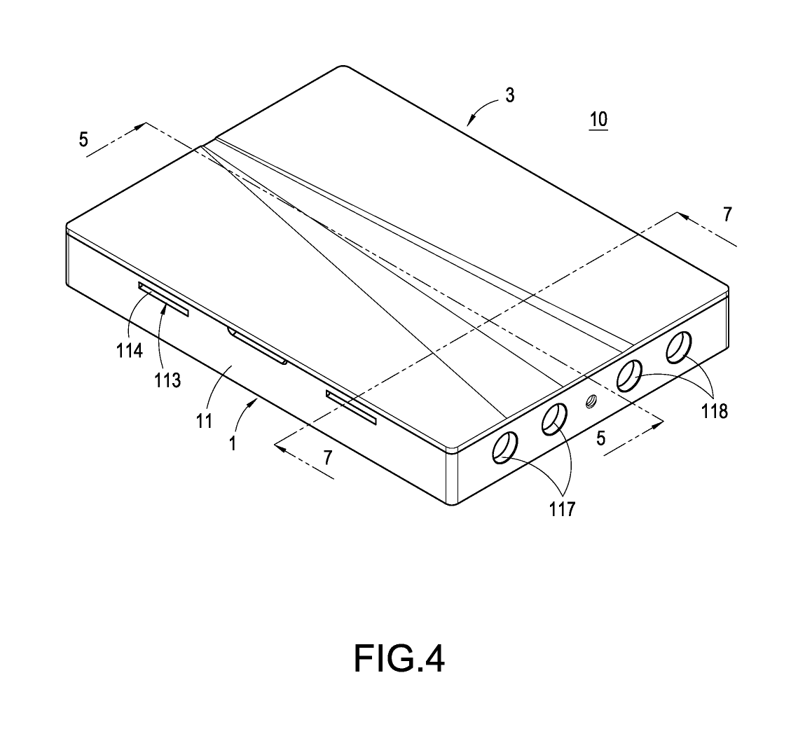

As shown in FIGS. 4-6, the electronic apparatus 10 for a solar power system of the present invention uses the first shell 1 having the surrounding plate 11, the receiving space 12 formed in the surrounding plate 11, and the clasp portions 13 disposed on the inner side of the surrounding plate 11 in which the surrounding notch 111 is formed on the top of the surrounding plate 11, the waterproof member 2 filled in the surrounding notch 111, and the second shell 3 connected to the first shell 1 and fitted to cover the receiving space 12 correspondingly in which the second shell 3 has a surrounding protrusion 31 and the clasp parts 32 disposed on the inner side of the surrounding protrusion 31. The clasp parts 32 snap fit the clasp portions 13 correspondingly to make the surrounding protrusion 31 embedded in the surrounding notch 111 such that the waterproof member 2 is clamped between the surrounding protrusion 31 and the surrounding plate 11. In this way, the surrounding protrusion 31 presses against and deforms the waterproof member 2 which further contacts against the surrounding plate 11 more tightly, improving the waterproof and dustproof of the electronic apparatus 10 for the solar power system.

FIGS. 4-6 show the operating state of the electronic apparatus 10 for a solar power system of the present invention. The electronic apparatus 10 uses the first shell 1 having the clasp portions 13 disposed on the inner side of the surrounding plate 11, the surrounding notch 111 formed on the top of the surrounding plate 11, the waterproof member 2 filled in the surrounding notch 111, and the second shell 3 having the clasp parts 32 disposed on the inner side of the surrounding protrusion 31. The clasp parts 32 snap fit the clasp portions 13 correspondingly to make the surrounding protrusion 31 embedded in the surrounding notch 111 such that the waterproof member 2 is clamped between the surrounding protrusion 31 and the surrounding plate 11. In this way, the clasp portions 13 disposed on the inner side of the surrounding plate 11 snap fit the clasp parts 32 disposed on the inner side of the surrounding protrusion 31 correspondingly to make the surrounding protrusion 31 pressed and embedded in the surrounding notch 111 and contact against the waterproof member 2 such that the waterproof member 2 is deformed to contact against the inner wall of the surrounding notch 111 and the surrounding protrusion 31 more tightly, which improves the waterproof and dustproof of the electronic apparatus 10 for the solar power system.

Moreover, the clasp portions 13 are disposed on the inner side of the surrounding plate 11 and the clasp parts 32 are disposed on the inner side of the surrounding protrusion 31. As such, the structures of the clasp portions 13 and the clasp parts 32 are not exposed to the outside of the electronic apparatus 10, not necessary to consider the aesthetic quality thereof. How to ensure a robust and tight snap fit between the clasp parts 32 and the clasp portions 13 is a major concern instead, which actually makes the surrounding protrusion 31 pressed and embedded in the surrounding notch 111 and contact against the waterproof member 2.

Further, the surrounding plate 11 has the inner wall 14 on which the clasp portion 13 is formed. There is a spacing s between the top of the inner wall 14 and the second shell 3 such that when the clasp part 32 snap fits the clasp portion 13 accordingly, the spacing s is disposed between the clasp part 32 and the clasp portion 13 to form a compressible space for the fine tune of the snap fit between the clasp part 32 and the clasp portion 13. Thus, the combination of the clasp part 32 and the clasp portion 13 can be made more robust and tighter.

In addition, the clasp part 32 is a latch block 331 protruding from the end of the pressing block 33; the clasp portion 13 is a lock slot 141 formed on the inner wall 14; the latch block 331 snap fits the lock slot 141 correspondingly. As a result, the electronic apparatus 10 for the solar power system just uses these simple components to enhance the force applied by the surrounding protrusion 31 to press against the waterproof member 2.

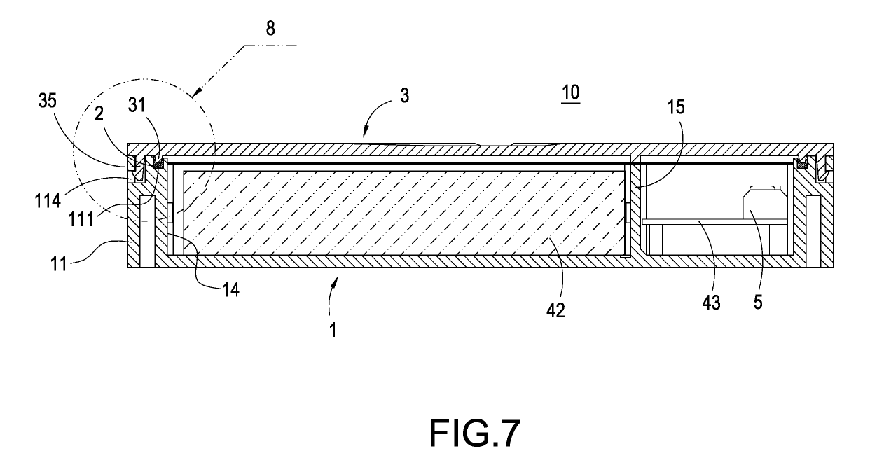

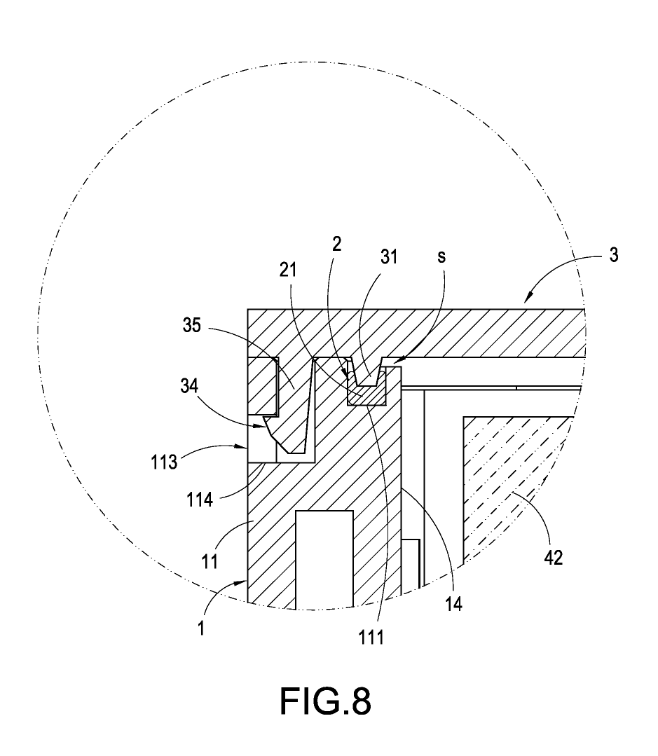

Also, the shells of the traditional electronic apparatus for the solar power system are almost combined by means of the screw fastening. When the traditional electronic apparatus needs maintenance, additional tools (e.g., screw drivers) are required to perform the uninstallation, which makes repairmen feel time consuming and inconvenient. However, in the electronic apparatus 10 for the solar power system of the present invention, referring to FIGS. 7 and 8, the clasp slots 113 are disposed on two opposite sides of the surrounding plate 11; the clasp blocks 34 extend from each of two opposite ends of the second shell 3.

The clasp blocks 34 snap fit the clasp slots 113 correspondingly such that the screw fastening is not required for the combination of the first shell 1 and the second shell 3, causing the electronic apparatus 10 for the solar power system to have the feature of easy assembly.

In the case that the electronic apparatus 10 for the solar power system is a combined apparatus integrating a solar junction and a power inverting mechanism, a plurality of AC output holes 117 and a plurality of DC output holes 118 are disposed on a side of the surrounding plate 11. The AC output holes 117 and the DC output holes 118 are disposed on one side, facilitating the external electrical connection to the electronic apparatus 10 for the solar power system.

Also, the partitions 15 extend from the first shell 1 toward the receiving space 12 and are disposed among the first PCB 41, the second PCB 42, and the third PCB 43 to provide electrical insulation among these PCBs, which prevents sparks from occurring among these PCBs. Thus, the electronic apparatus 10 for the solar power system can have greater operating security.

What is claimed is:

1. An electronic apparatus (10) for a solar power system, comprising:
a first shell (1) having a surrounding plate (11), a receiving space (12) formed in the surrounding plate (11), and at least one clasp portion (13) disposed on an inner side of the surrounding plate (11), wherein a surrounding notch (111) is formed on the top of the surrounding plate (11);
a waterproof member (2) filled in the surrounding notch (111); and
a second shell (3) connected to the first shell (1) and fitted to cover the receiving space (12) correspondingly, wherein the second shell (3) has a surrounding protrusion (31) and at least one clasp part (32) disposed on an inner side of the surrounding protrusion (31), wherein the at least one clasp part (32) snap fits the at least one clasp portion (13) correspondingly to make the surrounding protrusion (31) embedded in the surrounding notch (111) such that the waterproof member (2) is clamped between the surrounding protrusion (31) and the surrounding plate (11).

2. The electronic apparatus (10) for the solar power system according to claim 1, wherein at least one pressing block (33) extends from the second shell (3) toward the receiving space (12), wherein the at least one clasp part (32) is formed at the end of the at least one pressing block (33), wherein the surrounding plate (11) has an inner wall (14) on which the at least one clasp portion (13) is formed.

3. The electronic apparatus (10) for the solar power system according to claim 2, wherein there is a spacing between the top of the inner wall (14) and the second shell (3).

4. The electronic apparatus (10) for the solar power system according to claim 2, wherein the numbers of the at least one pressing block (33) and the at least one clasp portion (13) are both greater than one, wherein the pressing blocks (33) are disposed at opposite ends of the second shell (3) and the clasp portions (13) are disposed on opposite sides of the inner wall (14).

5. The electronic apparatus (10) for the solar power system according to claim 2, wherein the at least one clasp part (32) is a latch block (331) protruding from the end of the at least one pressing block (33), wherein the at least one clasp portion (13) is a lock slot (141) formed on the inner wall (14), wherein the latch block (331) snap fits the lock slot (141) correspondingly.

6. The electronic apparatus (10) for the solar power system according to claim 1, wherein at least one clasp slot (113) is disposed on each of two opposite sides of the surrounding plate (11), wherein at least one clasp block (34) extends from each of two opposite ends of the second shell (3), wherein the at least one clasp block (34) snap fits the at least one clasp slot (113) correspondingly.

7. The electronic apparatus (10) for the solar power system according to claim 6, wherein the at least one clasp block (34) is an L-shaped protrusion (35) protruding from the second shell (3), wherein the at least one clasp slot (113) is an L-shaped slot (114) formed from the top of the surrounding plate (11) and from the inside to the outside thereof, wherein the L-shaped protrusion (35) snap fits the L-shaped slot (114) correspondingly.

8. The electronic apparatus (10) for the solar power system according to claim 1, wherein the waterproof member (2) is a waterproof ring (21).

9. The electronic apparatus (10) for the solar power system according to claim 8, wherein the waterproof ring (21) is made of a PU foam disposed in the surrounding notch (111).

10. The electronic apparatus (10) for the solar power system according to claim 1, wherein the electronic apparatus (10) for the solar power system is a combined apparatus integrating a solar junction and a power inverting mechanism .

11. The electronic apparatus (10) for the solar power system according to claim 10, further comprising a PCB (4) and a plurality of connectors (5), wherein the PCB (4) and the connectors (5) are electrically connected to one another in the receiving space (12).

12. The electronic apparatus (10) for the solar power system according to claim 11, wherein the PCB (4) comprises a first PCB (41), a second PCB (42), and a third PCB (43) which are electrically connected to one another, wherein both the first PCB (41) and the second PCB (42) form a power inverting circuit, wherein the third PCB (43) forms a grounding circuit, wherein the connectors (5) are welded on the third PCB (43).

13. The electronic apparatus (10) for the solar power system according to claim 12, wherein a plurality of partitions (15) extend from the first shell (1) toward the receiving space (12), wherein the partitions (15) are disposed among the first PCB (41), the second PCB (42), and the third PCB (43).

14. The electronic apparatus (10) for the solar power system according to claim 1, wherein a plurality of AC output holes (117) and a plurality of DC output holes (118) are disposed on a side of the surrounding plate (11).
